(19) United States
(12) Patent Application Publication
(10) Pub. No.: US 2005/0272190 A1
(43) Pub. Date: Dec. 8, 2005

(54) Methods of fabricating fin field-effect transistors having silicide gate electrodes and related devices

(76) Inventors: Deok-Hyung Lee, Seoul (KR); Yu-Gyun Shin, Gyeonggi-do (KR); Jong-Wook Lee, Gyeonggi-do (KR)

Correspondence Address: MYERS BIGEL SIBLEY & SAJOVEC, PO BOX 37428, RALEIGH, NC, 27627, US

(21) Appl. No.: 11/143,561

(22) Filed: Jun. 2, 2005

(30) Foreign Application Priority Data
Jun. 2, 2004 (KR) 2004-40084

(51) Int. Cl. H01L 21/338; H01L 29/76

(52) U.S. Cl. 438/176; 257/314

(57) ABSTRACT

A method of fabricating a fin field-effect transistor includes forming a fin-shaped active region having first and second source/drain regions therein and a channel region therebetween vertically protruding from a semiconductor substrate, and forming a polysilicon gate electrode on sidewalls of the channel region. Opposing sidewalls of the polysilicon gate electrode are silicided towards a central region thereof to form a silicide gate electrode. Related devices are also discussed.

### CROSS-REFERENCE TO RELATED APPLICATIONS

The present application claims priority under 35 U.S.C. § 119 to Korean Patent Application 2004-40084 filed on Jun. 2, 2004, the contents of which is hereby incorporated by reference herein in its entirety.

### BACKGROUND OF THE INVENTION

The present invention relates to semiconductor devices, and more specifically, to methods of fabricating fin field-effect transistors and related devices.

Over the last few decades, silicon-based integrated circuit devices, such as field-effect transistor (FET) devices and metal-oxide semiconductor (MOS) devices, have been fabricated to provide increased speed, higher integration density, and improved functionality. Typical MOS devices are formed in a substrate having higher carrier concentration density source/drain regions separated by a lower carrier concentration density channel region. The channel region is controlled by a gate electrode that is electrically separated from the channel region by a gate insulation layer.

Because of increased needs for higher integration density in addition to higher performance, increased speed, lower power-consumption, and reduced cost, many problems may occur which may degrade transistor characteristics. For example, short channel effects such as punch-through, drain induced barrier lowering (DIBL), and subthreshold swing, increased parasitic capacitance between the junction region and the substrate, and increased leakage current may occur. Punch-through, for instance, may be caused by the shortened channel length of the field-effect transistor as transistor size is reduced.

Therefore, various structures and/or processes have been developed to provide advancements over conventional planar field effect transistors. More specifically, several transistors and/or techniques have been developed to address problems of conventional planar bulk-MOS devices. For example, newly-designed transistors may include ultra-thin body transistors (where the channel region is formed in a thin body layer) and double-gate transistors (where one channel region is controlled by two gates that are separated from the channel region by gate insulation layers).

However, such technologies may not be practical and/or compatible with conventional semiconductor fabrication techniques. For example, production costs for ultra-thin body transistors may be relatively expensive compared to those for conventional bulk-MOS devices. In addition, ultra-thin body transistors may be more susceptible to floating body effects, heat conduction effects, and/or current limitations due to the thickness of the body.

Meanwhile, although double-gate semiconductor devices may allow for control of the channel at two sidewalls thereof and may improve leakage current, they may also have disadvantages such as increased cost, reduced production rate, and more complex fabrication techniques. More specifically, it may be difficult to arrange and/or align the upper gate and the lower gate in double-gate semiconductor devices. When the upper and lower gates are misaligned, variations in device performance and/or increased parasitic capacitance may result. Thus, it may be difficult to achieve high integration density in double-gate semiconductor devices.

To address these problems, three-dimensional semiconductor devices, such as fin field-effect transistors (FinFETs) have been developed. FinFETs may include a channel region formed in a vertically-protruding semiconductor fin, a gate insulation layer formed on the semiconductor fin, and a gate electrode extending around the semiconductor fin.

Technologies for fabricating FinFETs may be categorized into those including a silicon-on-insulator (SOI) substrate and those including a bulk silicon substrate. For example, U.S. Pat. No. 6,413,802 to Hu et al. discloses a method of forming a FinFET on a SOI substrate, and U.S. Pat. No. 5,844,278 to Mizuno et al. discloses a method of forming a FinFET on a bulk silicon substrate. The FinFETs disclosed in these patents may employ polysilicon as a gate electrode material. However, in FinFETs having a polysilicon gate, device operation speed may be decreased due to RC delay as device integration density increases.

In “FinFET Scaling to 10 nm Gate Length” by Bin Yu et al. (IEEE 2002), the contents of which is incorporated by reference herein, gate structures formed of a silicide layer on a polysilicon layer are disclosed. According to the method proposed by Yu et al., a silicon fin may be formed by etching a SOI substrate, and then a polysilicon layer is formed crossing over the silicon fin (i.e., on a top surface and sidewalls of the silicon fin). A nickel silicide layer may be formed on a top surface of the polysilicon layer to form a double-layer gate electrode. Therefore, gate resistance may be reduced as compared to a single layer polysilicon gate. However, due to the thickness of the gate stack (polysilicon/nickel silicide) on the silicon fin, parasitic capacitance between the gate electrode and a source/drain contact plug may not be improved and RC delay may still be a problem.

In addition, in “Metal-gate FinFET and Fully-depleted SOI Devices Using Total Gate Silicidation” by Jakub Kedzierski et al. (IEDM 2002), the contents of which are incorporated by reference herein, a method of total polysilicon silicidation is disclosed. According to the method proposed by Kedzierski et al., a polysilicon gate layer may be formed crossing over a silicon fin, and then a nickel layer may be formed on a top surface of the polysilicon layer. A thermal silicidation process may then be performed. As such, the threshold voltage of a CMOS device may be controlled by total silicidation of the polysilicon gate layer. However, a thick silicide layer may be formed in the junction region, and leakage current may occur therein. In addition, dopant redistribution may occur due to the thermal budget.

### SUMMARY OF THE INVENTION

According to some embodiments of the present invention, a method of fabricating a fin field-effect transistor may include forming a fin-shaped active region having first and second source/drain regions therein and a channel region therebetween vertically protruding from a semiconductor substrate, and forming a polysilicon gate electrode on sidewalls of the channel region. Opposing sidewalls of the polysilicon gate electrode may be silicided towards a central region thereof to form a silicide gate electrode.

In some embodiments, siliciding opposing sidewalls of the polysilicon gate electrode may include forming a refractory metal layer on the opposing sidewalls of the polysilicon gate electrode, and annealing the refractory metal layer to silicide the polysilicon gate electrode. As such, the polysilicon gate electrode may be silicided from an interface between the refractory metal layer and the opposing sidewalls of the polysilicon gate electrode towards the central region thereof.

In other embodiments, the method may further include forming a metal gate electrode on an upper surface of the polysilicon gate electrode. A metal nitride layer may be formed on the upper surface of the polysilicon gate electrode prior to forming the metal gate electrode thereon to prevent silicidation therebetween. For example, the metal gate electrode may be a word line formed of tungsten, molybdenum, and/or titanium, and the metal nitride layer may be formed of titanium nitride and/or tungsten nitride.

In some embodiments the method may further include forming a gate insulation layer on an upper surface and on the sidewalls of the channel region. The polysilicon gate electrode may be formed on the upper surface of the channel region to form a triple-gate FinFET device.

In other embodiments, the method may further include forming a capping insulation layer on an upper surface of the fin-shaped active region between the polysilicon gate electrode and the channel region to form a double-gate FinFET device.

In some embodiments, a lower insulation layer may be formed on the substrate adjacent lower sidewalls of the fin-shaped active region, and an upper insulation layer may be formed on the lower insulation layer to define a trench surrounding the fin-shaped active region. A vertical portion of the polysilicon gate electrode may be formed in the trench on the sidewalls of the channel region, and a horizontal portion of the polysilicon gate electrode may be formed on an upper surface of the upper insulation layer. The upper insulation layer may extend away from the substrate to a height greater than that of the fin-shaped active region. Moreover, the silicide gate electrode and/or the first and second source/drain regions exposed by the trench may be doped using a tilted ion implantation process.

According to further embodiments of the present invention, a method of forming a fin field-effect transistor may include forming a fin-shaped active region having first and second source/drain regions therein and a channel region therebetween vertically protruding from a semiconductor substrate. A lower insulation layer may be formed on the substrate adjacent lower sidewalls of the fin-shaped active region, and an upper insulation layer may be formed on the lower insulation layer to define a trench surrounding the fin-shaped active region. A polysilicon gate electrode may be formed having a vertical portion in the trench on sidewalls of the channel region and a horizontal portion on an upper surface of the upper insulation layer. A metal nitride layer may be formed on an upper surface of the polysilicon gate electrode, and a metal gate electrode may be formed on the metal nitride layer. A refractory metal layer may be formed on opposing sidewalls of the polysilicon gate electrode, the metal nitride layer, and the metal gate electrode. The refractory metal layer may be annealed to form a silicide gate electrode having an increasing degree of silicidation from an interface between the refractory metal layer and opposing sidewalls of the silicide gate electrode towards a central region thereof.

According to some embodiments of the present invention, a FinFET device may include a semiconductor substrate, a fin-shaped active region having first and second source/drain regions therein and a channel region therebetween vertically protruding from the semiconductor substrate, and a silicide gate electrode on sidewalls of the channel region. The silicide gate electrode may have an increasing degree of silicidation from opposing sidewalls thereof towards a central region thereof.

In some embodiments, the FinFET device may include a metal gate electrode on an upper surface of the silicide gate electrode. The device may further include a metal nitride layer on the upper surface of the silicide gate electrode between the metal gate electrode and the silicide gate electrode. The metal gate electrode may be a word line formed of tungsten, molybdenum, and/or titanium, and the metal nitride layer may be formed of titanium nitride and/or tungsten nitride.

In other embodiments, the FinFET device may include a gate insulation layer on an upper surface and on the sidewalls of the channel region. The silicide gate electrode may extend onto the upper surface of the channel region to define a triple-gate FinFET device.

In some embodiments, the FinFET device may include a capping insulation layer on an upper surface of the fin-shaped active region. The capping layer may separate the silicide gate electrode and an upper surface of the channel region to define a double-gate FinFET device. The silicide gate electrode may extend away from the substrate on the sidewalls of the channel region to a height approximately equal to that of the capping layer.

In other embodiments, the FinFET device may include a lower insulation layer on the substrate adjacent lower sidewalls of the fin-shaped active region, and an upper insulation layer on the lower insulation layer defining a trench surrounding the fin-shaped active region. The silicide gate electrode may include a vertical portion in the trench on the sidewalls of the channel region and a horizontal portion on an upper surface of the upper insulation layer. The upper insulation layer may extend away from the substrate beyond the fin-shaped active region.

In some embodiments, the silicide gate electrode may be doped with n type or p type impurities, and the source/drain regions may include the same type of impurities doped in the silicide gate electrode.

### BRIEF DESCRIPTION OF THE DRAWINGS

FIG. 1 is a plan view of a semiconductor device in accordance with some embodiments of the present invention;

FIGS. 2A through 2C are cross-sectional views of a semiconductor device in accordance with some embodiments of the present invention taken along lines I-I, II-II, and III-III of FIG. 1, respectively;

FIGS. 3A through 3C are cross-sectional views of a semiconductor device in accordance with further embodiments of the present invention taken along lines I-I, II-II, and III-III of FIG. 1, respectively;

FIGS. 4A through 4C are cross-sectional views of a semiconductor device in accordance with still further embodiments of the present invention taken along lines I-I, II-II, and III-III of FIG. 1, respectively;

FIGS. 5A through 5C are cross-sectional views of a semiconductor device in accordance with yet further embodiments of the present invention taken along lines I-I, II-II, and III-III of FIG. 1, respectively;

FIGS. 6 through 14 are perspective views of a semiconductor substrate illustrating exemplary intermediate fabrication steps in methods of fabricating a semiconductor device in accordance with some embodiments of the present invention;

FIG. 15 is a cross-sectional view of a semiconductor device according to some embodiments of the present invention taken along line IV-IV of FIG. 13;

FIGS. 16A through 23A are perspective views of a semiconductor substrate illustrating methods of fabricating a semiconductor device in accordance with further embodiments of the present invention;

FIGS. 16B through 23B are cross-sectional views taken along a line V-V of FIG. 16A; and

FIG. 24 is a diagram for illustrating methods of tilted ion implantation according to some embodiments of the present invention.

### DETAILED DESCRIPTION OF EMBODIMENTS OF THE INVENTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an ” and “the” are intended to include the plural forms as well, unless the context clearly indicates otherwise. It will also be understood that the term “and/or” as used herein refers to and encompasses any and all possible combinations of one or more of the associated listed items.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. All publications, patent applications, patents, and other references mentioned herein are incorporated by reference in their entirety.

In addition, although only a single semiconductor device is illustrated in the drawings, numerous semiconductor devices may be formed simultaneously. Moreover, methods of forming semiconductor devices in accordance with embodiments of the present invention may be applicable to a DRAM cell transistor, a logic circuit, a nonvolatile memory device, a cell transistor in SRAM, a switching device, a CMOS device, etc.

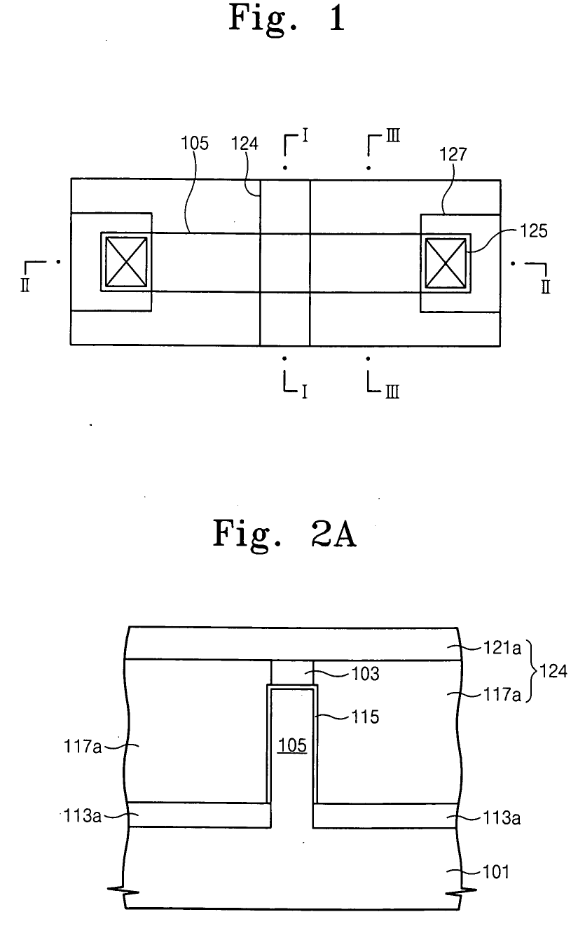

FIG. 1 is a plan view of a semiconductor device in accordance with the some embodiments of the present invention. Referring now to FIG. 1, a semiconductor fin 105 including a top/upper surface and opposing sidewalls vertically protrudes from a substrate. A gate electrode 124 is formed on the sidewalls and a top surface of the semiconductor fin 105, and crosses over the semiconductor fin 105 as such. Source/drain regions are located in the fin 105 at opposite sides of the gate electrode 124. An inversion layer channel region may be formed at the sidewalls and the top surface of the fin 105 between the source/drain regions. In some embodiments, a capping layer may be formed on the top surface of the fin 105. In such a case, the sidewalls of the fin 105 may serve as a channel region. Source/drain contacts 125 are formed on the source/drain regions, and a conductor 127 is electrically connected to each source/drain contact 125.

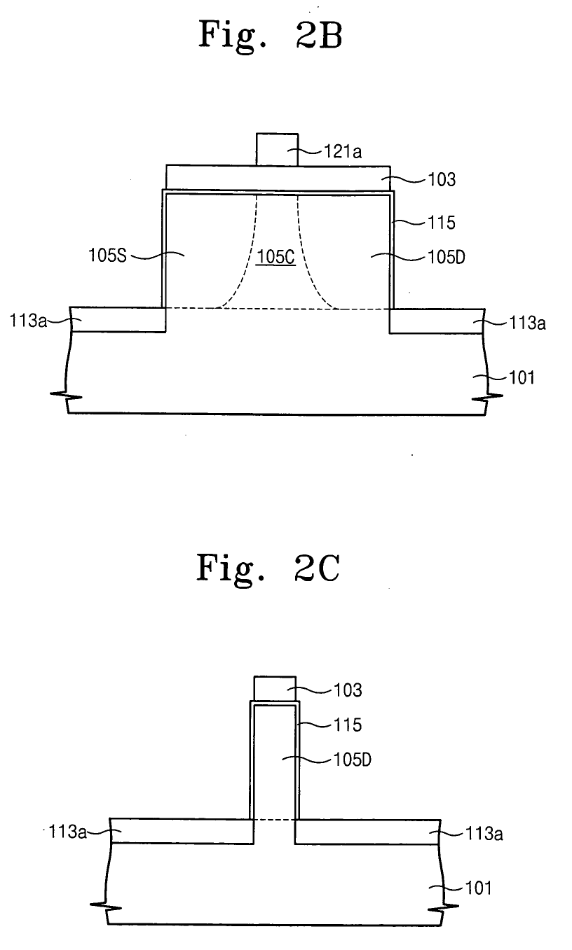

FIGS. 2A through 2C are cross-sectional views of a semiconductor device according to some embodiments of the present invention taken along lines I-I, II-II, and III-III of FIG. 1, respectively. Referring now to FIGS. 1, 2A, 2B, and 2C, a substrate 101 includes a semiconductor fin 105 vertically protruding therefrom. Neighboring fins may be electrically isolated by a device isolation layer 113a. A gate insulation layer 115 is formed on a top/upper surface and on opposing sidewalls of the semiconductor fin 105. A capping layer 103 also is formed on the top surface of the semiconductor fin 105. The gate electrode 124 includes a word line 121a and a gate electrode 117a for controlling the channel. As described herein, the gate electrode 117a for controlling the channel may be referred to as a silicide gate electrode, and the word line 121a may be referred to as a low-resistance metal gate electrode. The silicide gate electrode 117a is formed on the opposing sidewalls of the semiconductor fin 105, with the gate insulation layer 115 therebetween. In addition, the silicide gate electrode 117a is formed on sidewalls of the capping layer 103. In some embodiments, a top surface of the silicide gate electrode 117a may be formed to a same or similar height as that of the capping layer 103. The low-resistance gate electrode 121a is formed on the silicide gate electrode 117a and the capping layer 103.

Portions of the semiconductor fin 105 at opposite sides of the low-resistance metal gate electrode 121a are source/drain regions 105S and 105D, and the portion of the semiconductor fin 105 under the low-resistance metal gate electrode 121a and adjacent the silicide gate electrode 117a is a channel region 105C.

As shown in FIGS. 2A to 2C, the opposing sidewalls of the semiconductor fin 105 (i.e., the channel region) are controlled by the silicide gate electrode 117a. Accordingly, the semiconductor devices in FIGS. 2A through 2C are called double-gate FinFETs. As is well known, the silicide gate electrode 117a is formed by a reaction between silicon and metal materials. For example, silicon, nickel, titanium, cobalt, etc. may be used to react with a silicon layer to form the silicide gate electrode 117a. The silicide gate electrode 117a may reduce device threshold voltage as compared to a conventional polysilicon gate. This may be due to differences in work functions of silicon and silicide. As such, impurity dopant concentration may be reduced. In addition, the threshold voltage of the device may be adjusted by altering the dopant concentration. Furthermore, when p type impurities (for PMOS devices) and n type impurities (for NMOS devices) are injected, dual gate CMOS devices can be formed.

In some embodiments, the low-resistance metal gate electrode 121a may be a tungsten silicide layer formed by a deposition process.

Although not shown, a metal nitride layer, such as a tungsten nitride layer and/or a titanium nitride layer, may be formed between the low-resistance metal gate electrode 121a and the silicide gate electrode 117a.

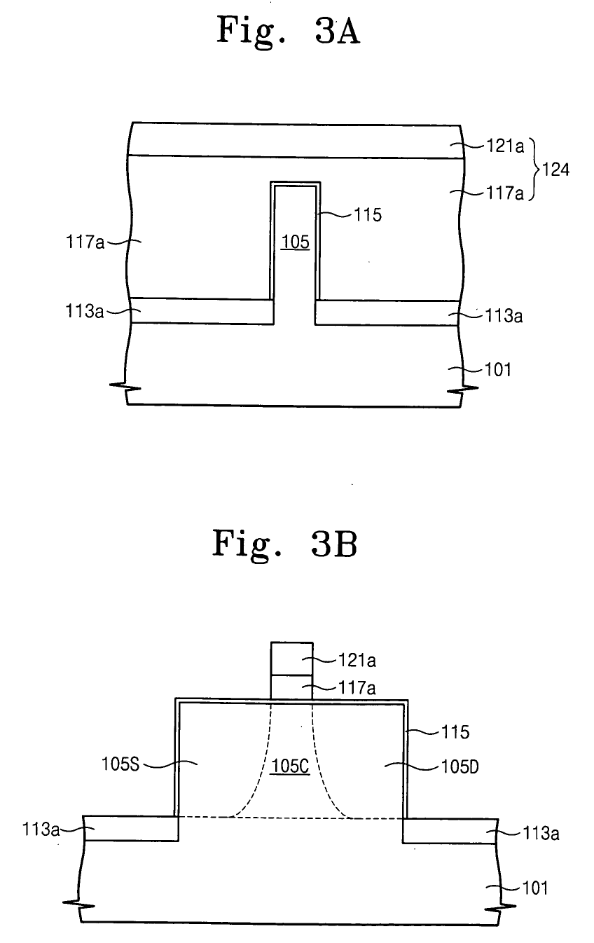

FIGS. 3A through 3C are cross-sectional views of a semiconductor device in accordance with further embodiments of the present invention taken along lines I-I, II-II, and III-III of FIG. 1, respectively.

In contrast to the semiconductor devices described with reference to FIGS. 2A through 2C, the semiconductor devices illustrated in FIGS. 3A through 3C do not include a capping layer on a top surface of the semiconductor fin 105. Therefore, the silicide gate electrode 117a is formed on both opposing sidewalls and on the top surface of the semiconductor fin 105, with the gate insulation layer 115 therebetween. As a result, the silicide gate electrode 117a controls both the sidewalls of the semiconductor fin 105 and the top surface thereof. Accordingly, the semiconductor devices of FIGS. 3A through 3C are called triple-gate FinFETs.

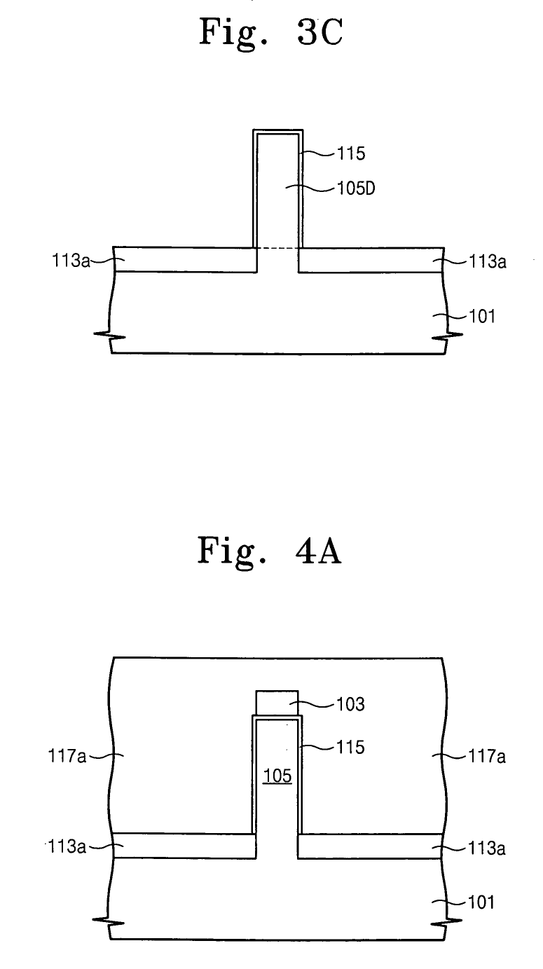

FIGS. 4A through 4C are cross-sectional views of a semiconductor device in accordance with still further embodiments of the present invention taken along lines I-I, II-II, and III-III of FIG. 1, respectively.

In contrast with the semiconductor devices described with reference to FIGS. 3A through 3C, the semiconductor devices of FIGS. 4A through 4C do not include a low-resistance metal gate electrode on the silicide gate electrode 117a. In other words, the low-resistance metal gate electrode may be formed of the same material as the silicide gate electrode 117a. As such, the gate stack may include only the silicide gate electrode 117a. In addition, a capping layer may not be formed on a top surface of the semiconductor fin 105, and, as such, the silicide gate electrode 117a may control both the opposing sidewalls and the top surface of the semiconductor fin 105.

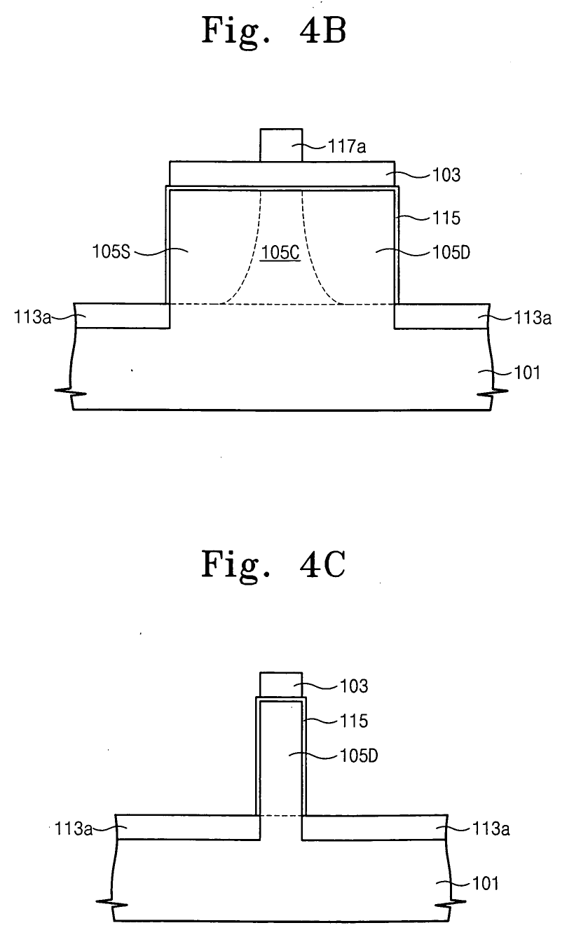

FIGS. 5A through 5C are cross-sectional views of a semiconductor device in accordance with yet further embodiments of the present invention taken along lines I-I, II-II, and III-III of FIG. 1, respectively.

In contrast with the semiconductor devices described with reference to FIGS. 2A through 2C, the silicide gate electrode 117a of FIGS. 5A through 5C include a horizontal portion 117h and a vertical portion 117v. In addition, an upper insulating layer 120 and a buffer nitride layer 114a are formed on the device isolation layer 113a. The vertical portion 117v of the silicide gate electrode 117a is formed on opposing sidewalls of the semiconductor fin 105. The horizontal portion 117h of the silicide gate electrode 117a may be oriented at a right angle to the vertical portion 117v, and may be extended to be orthogonally connected to a vertical portion of a neighboring semiconductor fin. A top surface of the horizontal portion 117h may be practically the same height as the capping layer 103. A metal nitride layer 121b is formed under the low-resistance metal gate electrode 121a.

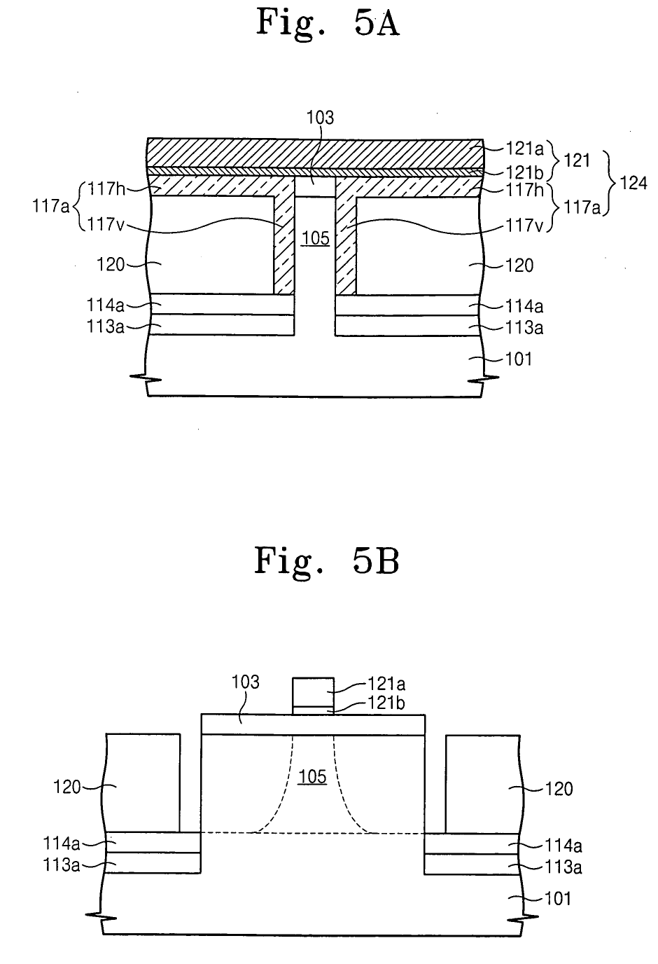

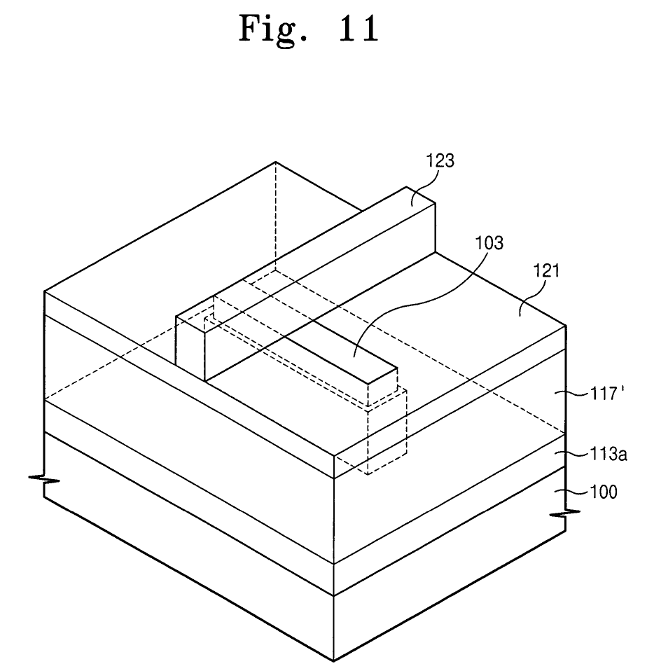

Methods of fabricating semiconductor devices in accordance with some embodiments of the present invention will now be described. First, referring to FIGS. 6 through 14, a method of fabricating semiconductor devices as illustrated in FIGS. 2A through 2C will be described.

As shown in FIG. 6, a fin mask pattern 103 is formed on a substrate 100. The fin mask pattern 103 may serve as a planarization stop layer in a subsequent process, and may also serve as a capping layer when not removed during the fabrication process. As such, the fin mask pattern 103 may be referred to herein as a capping layer.

The fin mask pattern 103 may be formed of a silicon nitride layer, and a silicon oxide layer may be formed between the substrate 100 and the silicon nitride layer as a buffer layer. The substrate 100 may include single crystalline bulk silicon formed by Czochralski crystal growth, a wafer cut from float zone crystal growth, an epitaxial layer, a buried oxide layer, and/or other region that is doped so as to improve device characteristics and/or provide a desired structure.

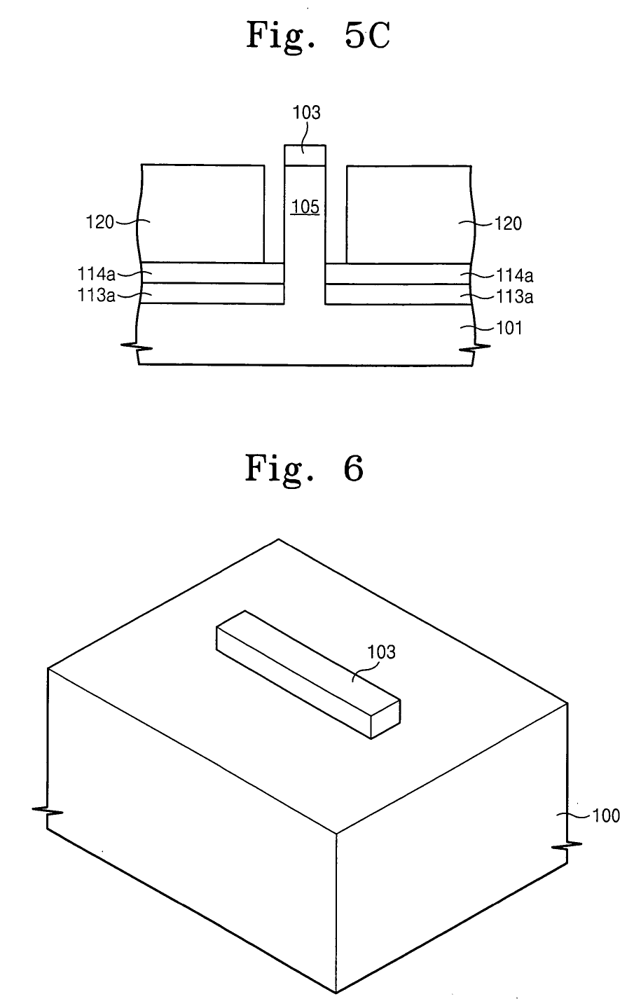

Referring to FIG. 7, a portion of the substrate 100 that is exposed by the fin mask pattern 103 is etched to remove a predetermined thickness therefrom. As a result, a semiconductor fin 105 is formed to a height corresponding to the removed thickness. The region surrounding the fin 105 formed by removing the predetermined thickness of the substrate 100 forms a trench 107.

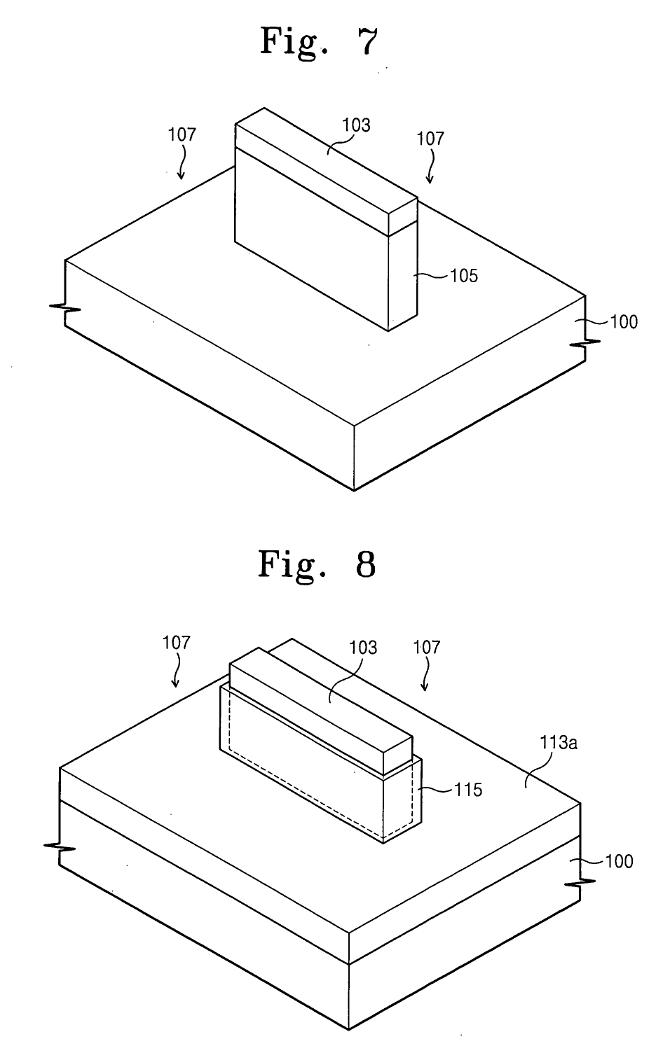

Referring now to FIG. 8, a device isolation layer 113a is formed to fill a bottom of the trench 107. The device isolation layer 113a is formed to electrically insulate neighboring semiconductor fins from the fin 105. If the substrate 100 is an SOI substrate, the device isolation layer 113a may not be formed. The device isolation layer 113a may be formed of an oxide layer using a vapor deposition method. More specifically, an oxide layer may be formed to fill the entire trench 107, and then a planarization process may be performed to expose the fin mask pattern 103. A wet etch and/or a dry etch is then performed to remove a portion of the oxide layer using the fin mask pattern 103 as an etch mask. Thus, sidewalls of the semiconductor fin 105 may be exposed. In some embodiments, a thermal oxidation process may be performed before forming the device isolation layer 113a, and an oxidation barrier layer may be formed. The thermal oxidation process may be performed to cure defects in the substrate from the etching process, and a thermal oxide layer may be formed as a result. The oxidation barrier layer may be formed, for example, of a silicon nitride layer to protect the semiconductor substrate 100 from oxidation.

Still referring to FIG. 8, a gate insulation layer 115 is formed on the exposed surfaces and/or sidewalls of the fin 105. The gate insulation layer 115 may be formed of various materials according to desired characteristics. For example, the gate insulation layer 115 may be formed of an oxide layer, a nitride layer, a high-K dielectric layer, and/or a silicate layer for use in a field effect transistor (FET) device. In addition, the gate insulation layer 115 may be formed of a multi-layer insulation structure, such as oxide/nitride/oxide layer to form a floating trap-type nonvolatile memory device, such as a SONOS device.

An ion implantation process for doping a channel region may be performed before forming the gate insulation layer 115. For example, after the semiconductor fin 105 is formed, a screen oxide layer may be formed and channel ions may be implanted. After the implantation process, the screen oxide layer may be removed, and the gate insulation layer 115 may be formed. When a thermal oxidation process is employed, an oxidation barrier layer may be formed, a device isolation layer 113a may be formed, and the oxidation barrier layer may be removed. The thermal oxide layer can then be used as the screen oxide layer for implanting channel ions.

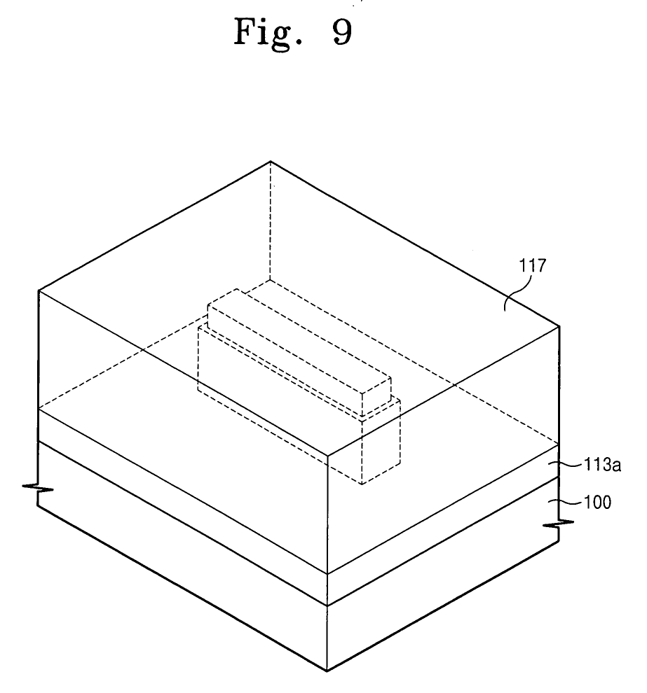

Referring to FIG. 9, a silicon layer 117 is formed on the fin mask pattern 103 to fill the trench 107. The silicon layer 117 may be formed by various methods, according to desired device characteristics. For instance, when a PMOS device is to be formed, the silicon layer 117 is formed of silicon doped with p type impurities. Alternatively, when an NMOS device is to be formed, the silicon layer 117 is formed of silicon doped with n type impurities. The impurities may be doped in-situ. Alternatively, if a non-doped silicon layer is formed, impurity ions may be doped therein by a subsequent process. The ion implantation process for doping a channel region may be carried out after forming a silicon layer, after patterning the silicon layer, and/or during an ion implantation process for forming source/drain regions.

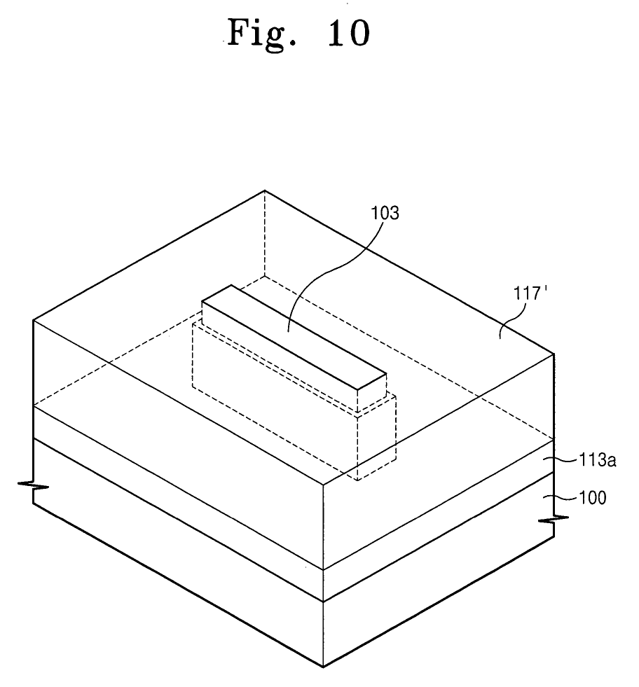

Referring now to FIG. 10, the silicon layer 117 is planarized until the fin mask pattern 103 is exposed. The planarization process may use a chemical-mechanical polishing (CMP) process and/or an etch back process.

Referring to FIG. 1, a metal layer 121 for forming a low-resistance gate electrode for use as a word line and a gate mask pattern 123 for defining the word line are formed on the planarized silicon layer 117′ and the fin mask pattern/capping layer 103. The metal layer 121 may be formed of tungsten, molybdenum, titanium and/or a combination thereof, for example, using chemical vapor deposition, physical vapor deposition, and/or atomic layer deposition. Alternatively, the metal layer 121 may be a tungsten silicide layer formed using vapor deposition. The gate mask pattern 123 may be formed of, for example, an oxide layer, a nitride layer, etc. for use in a conventional photolithographic process.

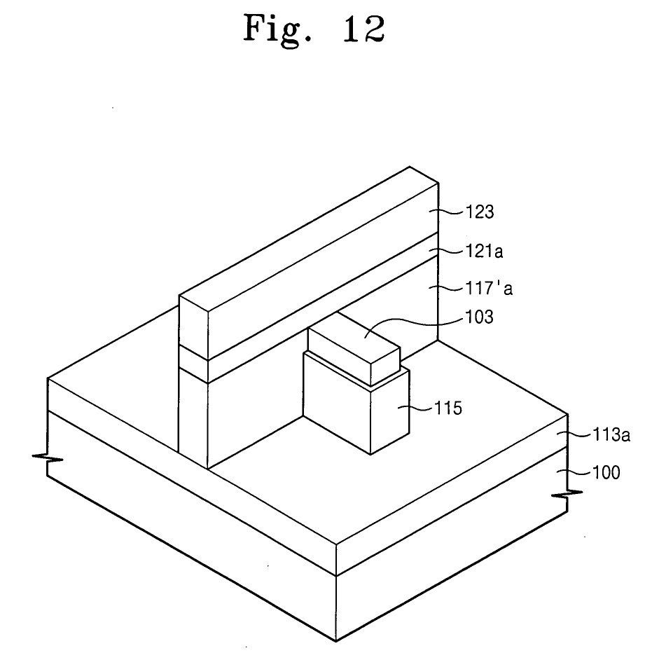

Referring to FIG. 12, lower material layers that are exposed by the gate mask pattern 123 (i.e., the metal layer 121 and the silicon layer 117′) are etched using the gate insulation layer 115 and the device isolation layer 113a as an etch stop layer. Therefore, a silicon pattern 117′a remains on opposing sidewalls of the semiconductor fin 105 under the gate mask pattern 123, and a metal pattern remains on the silicon layer 115 and the fin mask pattern 103 under the gate mask pattern 123. As such, a low-resistance metal gate electrode 121a is formed. Meanwhile, sidewalls of the fin 105 at opposite sides of the silicon pattern 117′a are protected by the gate insulation layer 115.

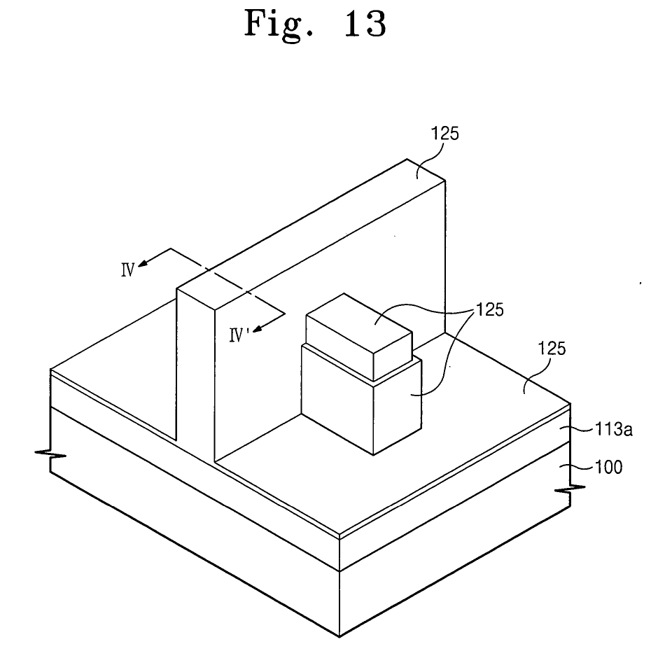

A silicidation process is then performed to provide a silicide gate and thereby reduce device threshold voltage, as will be explained with reference to FIG. 13. The dopant concentration in the channel region may also be reduced by converting the silicon pattern 117′a into a silicide layer. In other words, the silicon pattern 117′a may be converted into a silicide layer in order to control the work function of the gate. Referring now to FIG. 13, a refractory metal layer 125 is formed on the silicon pattern 117′a, the low-resistance metal gate electrode 121a, and the gate mask pattern 123 to convert the silicon pattern 117′a into the silicide layer. For example, the refractory metal layer may be a cobalt layer, a nickel layer, and/or a titanium layer. The refractory metal layer 125 may be formed of a material that is different from the low-resistance metal gate electrode 121a.

Still referring to FIG. 13, opposing sidewalls of the silicon pattern 117′a are in direct contact with the refractory metal layer 125, and a top surface of the silicon pattern 117′a is in contact with the metal pattern 121a. Meanwhile, the gate insulation layer 115 is disposed between sidewalls of the semiconductor fin 105 and the refractory metal layer 125 at opposite sides of the silicon pattern 117′.

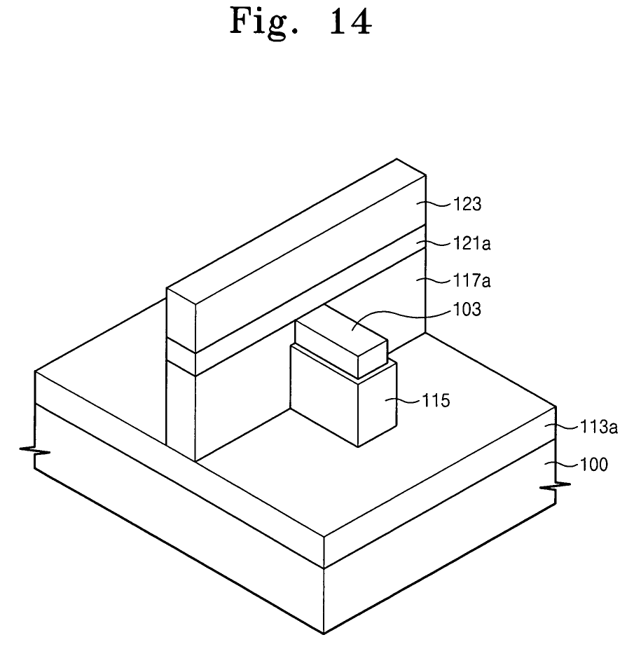

Referring now to FIG. 14, the silicon pattern 117′a is converted into the silicide pattern 117a by performing a thermal treatment to cause a silicidation reaction. The non-reacted portions of the refractory metal layer 125 are then selectively removed. According to some embodiments of the present invention, the opposing sidewalls of the silicon pattern 117′a directly contact the refractory metal layer 125, such that entire silicon pattern 117′a may be converted into the silicide gate electrode 117a. In other words, opposing sidewalls of the silicon pattern 117′a are silicided laterally towards a central portion thereof along a width direction of the semiconductor fin 105 to form the silicide gate electrode 117a. As such, some embodiments of the present invention may provide a silicide gate electrode having an increased degree of silicidation from opposing sidewalls thereof towards a central region thereof.

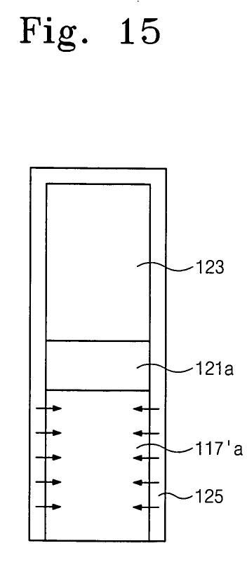

FIG. 15 is a cross-sectional view taken along line IV-IV in FIG. 13, illustrating arrows that indicate the direction of silicidation (i.e., along opposing sidewalls), according to some embodiments of the present invention.

An ion implantation process is subsequently carried out to form source/drain regions in the semiconductor fin 105 at opposite sides of the silicide gate electrode 117a.

In the method for fabricating a semiconductor device described above, a metal nitride layer such as a tungsten nitride layer, and/or a titanium nitride layer, may be formed on the planarized silicon layer 117′ before forming the metal layer 121. The metal nitride layer may prevent the metal layer 121 and the silicon layer 117′ from an undesirable reaction during the silicidation process.

Methods for fabricating the semiconductor devices illustrated in FIGS. 3A through 3C will now be described. Such methods may be similar to the methods described above with reference to FIGS. 6 through 15, except for the removal of the fin mask pattern 103 and the planarization method applied to the silicon layer 117. In particular, the semiconductor fin 105 is formed as shown in FIG. 7, but then the fin mask pattern 103 is removed. The silicon layer 117 is formed to a thickness sufficient to cover opposing sidewalls and a top/upper surface of the semiconductor fin 105. A planarization process for planarizing the top surface of the silicon layer 117 is then performed. However, the planarization process is performed for a predetermined time, based on the thickness of the silicon layer 117, such that the silicon layer 117 remains on the top surface of the semiconductor fin 105. Subsequently, similar processes are performed as in the methods shown in FIGS. 6 through 15. Accordingly, the silicide gate electrode 117a is also formed on the top surface of the semiconductor fin 105.

Methods for fabricating the semiconductor devices as illustrated in FIGS. 4A through 4C will now be explained. Such methods may be similar to the methods described above with reference to FIGS. 6 through 15, except for the planarization method applied to the silicon layer 117. Briefly, a semiconductor fin 105 is formed, and then a silicon layer 117 is formed to a thickness sufficient to cover sidewalls of the semiconductor fin 105, sidewalls of the fin mask pattern 103, and a top surface of the fin mask pattern 103. A planarization process is then performed to planarize the top surface of the silicon layer 117. The planarization process is performed for a predetermined time, considering the thickness of the silicon layer 117, so that the silicon layer 117 remains on a top surface of the fin mask pattern 103. The processes described with reference to FIGS. 6 through 15 are then performed. Accordingly, the silicide gate electrode 117a is formed on a top surface of the fin mask pattern 103 and on opposing sidewalls of the fin 105.

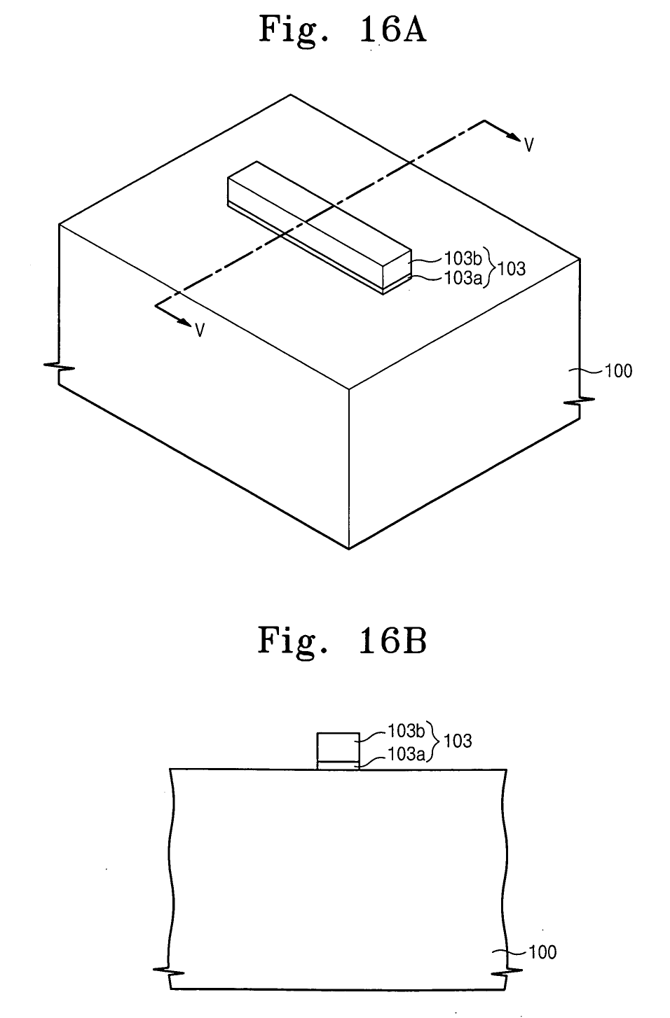

Methods for fabricating the semiconductor devices as illustrated in FIGS. 5A through 5C will now be described with reference to FIGS. 16A through 23A and FIGS. 16B through 23B. FIGS. 16B through 23B are cross-sectional views, taken along a line V-V in FIGS. 16A through 23A.

Referring now to FIGS. 16A and 16B, a fin mask pattern/capping layer 103 is formed to define a semiconductor fin on a semiconductor substrate 100. The capping layer 103 is formed of a pad oxide layer 103a and a pad nitride layer 103b that are sequentially stacked.

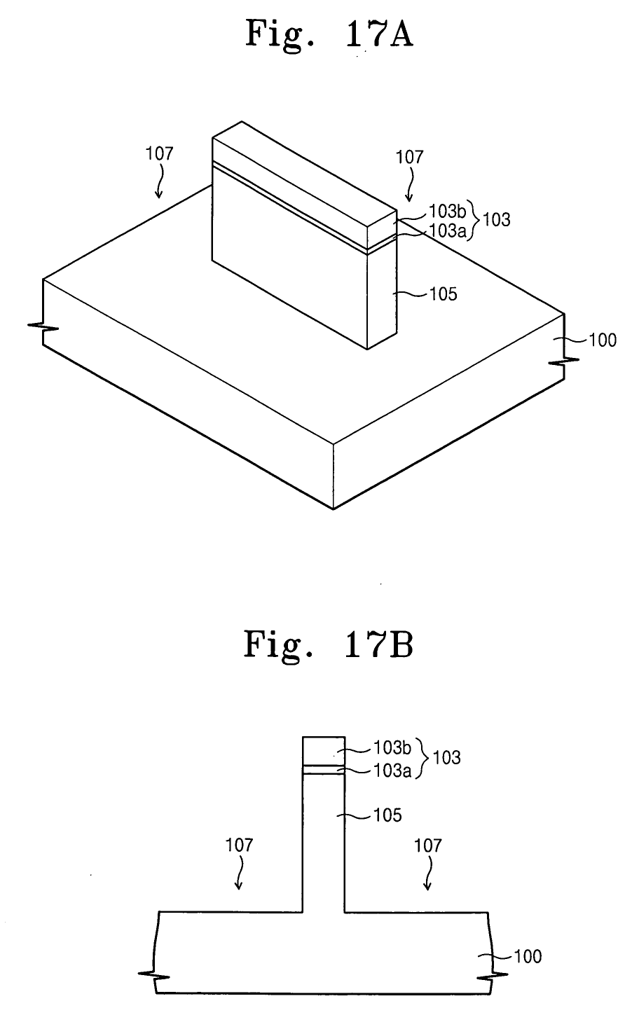

Next, referring to FIGS. 17A and 17B, portion of the semiconductor substrate exposed by the capping layer 103 are etched to a predetermined depth to form a trench 107, using the capping layer 103 as an etch mask. As such, a vertically protruding fin 105 is formed.

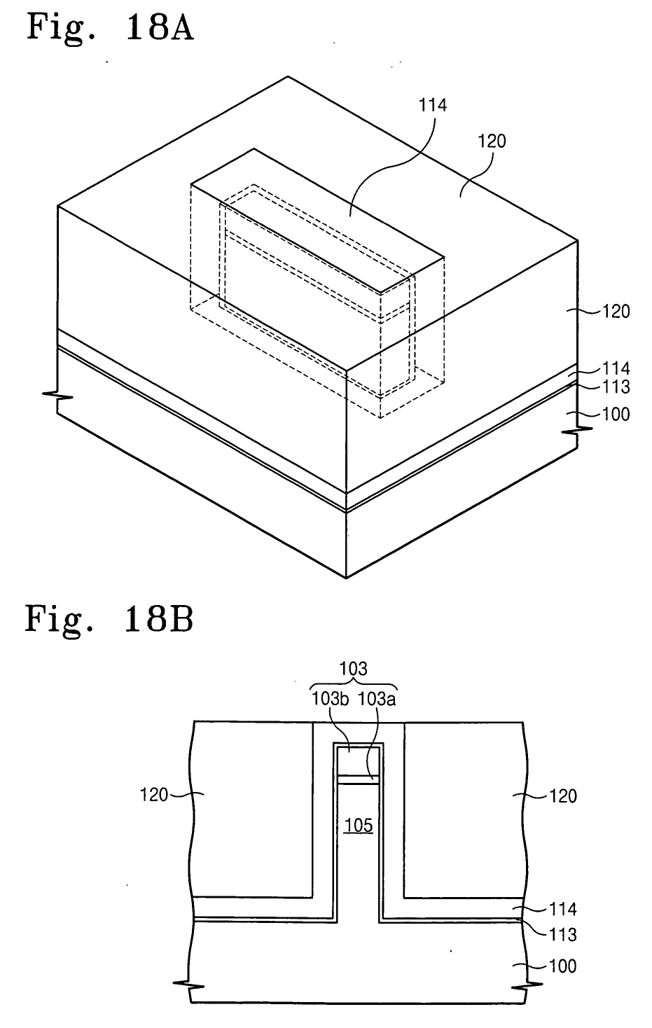

Referring to FIGS. 18A and 18B, an oxide liner 113 is formed on the substrate 100 including upper surfaces and sidewalls of the fin 105 using a chemical vapor deposition method. The oxide liner 113 may be formed to have an etch selectivity with respect to the pad oxide layer 103a of the capping layer 103. For example, when the pad oxide layer 103a is formed of a thermal oxide layer, the oxide liner 113 may be formed using a chemical vapor deposition method.

A nitride liner 114, which may be thicker than the oxide liner 113, is formed on the oxide liner 113. The nitride liner 114 and the oxide liner 113 form a lower insulation layer. The nitride liner 114 may be formed using well-known chemical vapor deposition methods.

An upper insulation layer is then formed on the nitride liner 114 to fill the trench 107. The upper insulation layer is planarized to expose the nitride liner 114 on the top surface of the fin 105, thereby forming an upper insulation layer 120. The upper insulation layer 120 may be formed of high-density plasma oxide layer. The planarization process may use a chemical mechanical polishing process using a slurry that selectively etches the oxide layer.

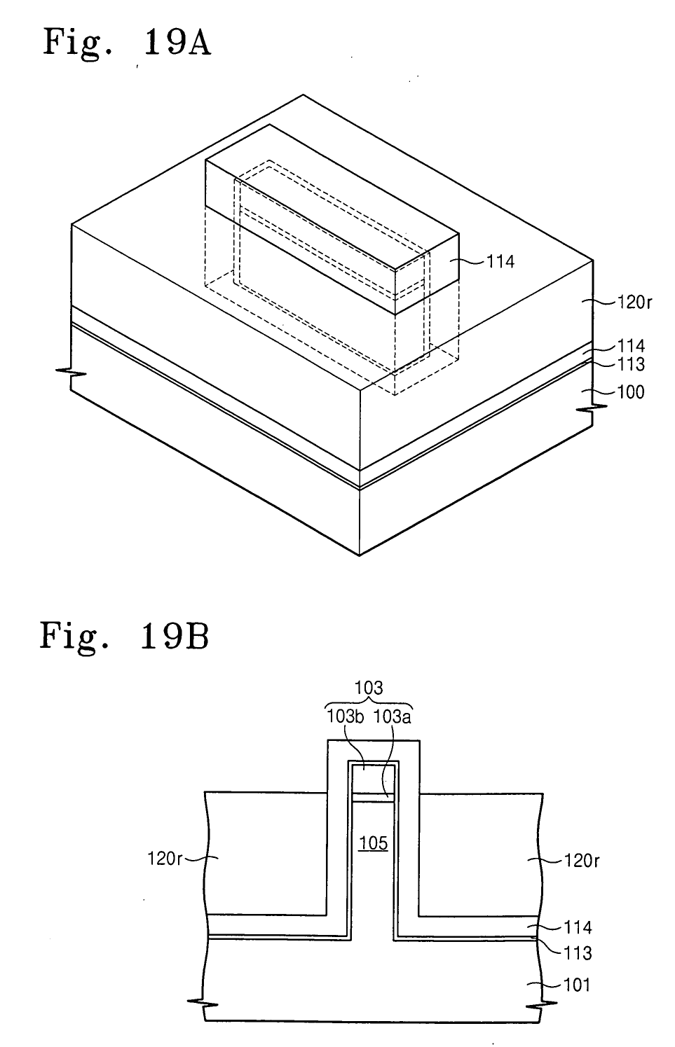

Referring to FIGS. 19A and 19B, an etch back process, for example, is performed to reduce the height of the planarized upper insulation layer 120. In some embodiments, the height of the recessed upper insulation layer 120r is higher than the top surface of the semiconductor fin 105. An etch gas capable of selectively etching the oxide layer 120 with respect to the nitride liner 114 may be used in the etch back process. Alternatively, a wet etch solution may be used.

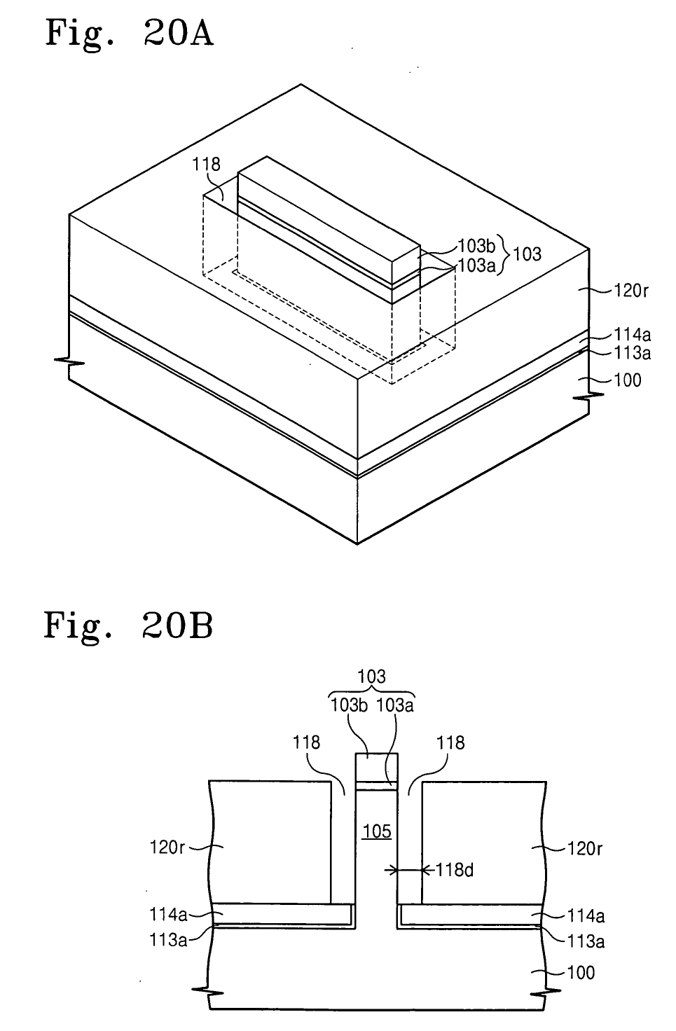

In some embodiments, the planarization process of FIG. 18A (and FIG. 18B) and the etch back process of FIG. 19A (and FIG. 19B) may be accomplished by a single process, that is, one etch back process. In other words, the upper insulation layer 120 may be formed on the nitride liner 114 to fill a trench 107, and then the etch back process may be performed such that the height of the recessed upper insulation layer 120r is lower than the top surface of the capping layer 103 but higher than the top surface of the semiconductor fin 105. In addition, the height of the upper insulation layer 120 may be lowered using the wet etch solution instead of the etch back process. In this case, a portion of the nitride liner 114 and a portion of the exposed oxide liner 113 can be removed to expose opposing sidewalls of the semiconductor fin 105 while simultaneously reducing the height of the upper insulation layer 120, as shown in FIGS. 20A and 20B.

Referring now to FIGS. 20A and 20B, a portion of the liner nitride layer 114 and a portion of the liner oxide layer 113 are removed to expose opposing sidewalls of the semiconductor fin 105. Therefore, a trench region 118 is formed between the recessed upper insulation layer 120r and the semiconductor fin 105. The trench region 118 may be formed around the semiconductor fin 105, for example, in the shape of a rectangular trench surrounding the opposing sidewalls of the semiconductor fin 105. The portion of the nitride liner layer 114 may be removed using a wet etch solution, such as phosphoric acid, or an appropriate dry etch gas. The oxide liner 113 may prevent the pad nitride layer 103b of the capping layer 103 from being etched. A portion of the exposed oxide liner 113 is then removed using the phosphoric acid or the etch gas to expose opposing sidewalls of the semiconductor fin 105 and the capping layer 103. As a result, lower insulation layers 113a and 114a remain on a bottom portion of the trench 107 surrounding lower sidewalls of the semiconductor fin 105. The amount of the nitride liner 114 and the oxide liner 113 that is removed may be based on the height of the semiconductor fin 105 and/or the desired height of the channel region, and it is well known to those skilled in the art that the removed amount may be altered depending on the particular processes employed and/or the desired device characteristics.

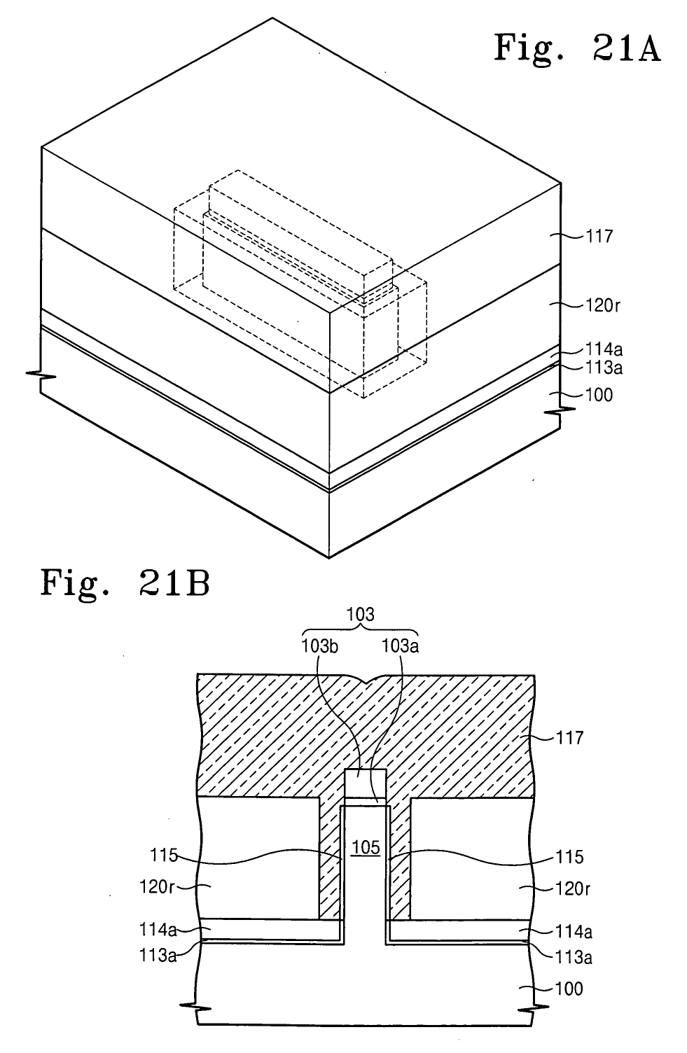

Referring now to FIGS. 21A through 21B, a gate insulation layer 115 is formed on the exposed sidewalls of the semiconductor fin 105, and then the trench region 118 is filled to form a silicon layer 117 on the recessed upper insulation layer 120r and the capping layer 103. The silicon layer 117 may be doped with a desired impurity type through an in-situ deposition process. Alternatively, if the silicon layer 117 is not doped in-situ, the desired types of impurities may be implanted using an ion implantation method in a subsequent process. When a CMOS device is formed, the in-situ doping process may be separately performed for the NMOS transistor and the PMOS transistor. Alternatively, if in-situ doping is not used, the ion-implantation process may be separately performed in a subsequent process.

In addition, when the silicon layer 117 is doped in-situ to have a conductivity type opposite to a desired type, a portion of the silicon layer 117 may be doped to form the desired conductivity type by implanting impurities in a subsequent process. For example, when a CMOS device is fabricated, a silicon layer may be doped in-situ to have a first conductivity type, and then an exposed portion of the silicon layer may be doped to have a second conductivity type in a subsequent ion implantation process. More specifically, the exposed portion of the silicon layer may be implanted with impurity ions of the second conductivity type in the subsequent process.

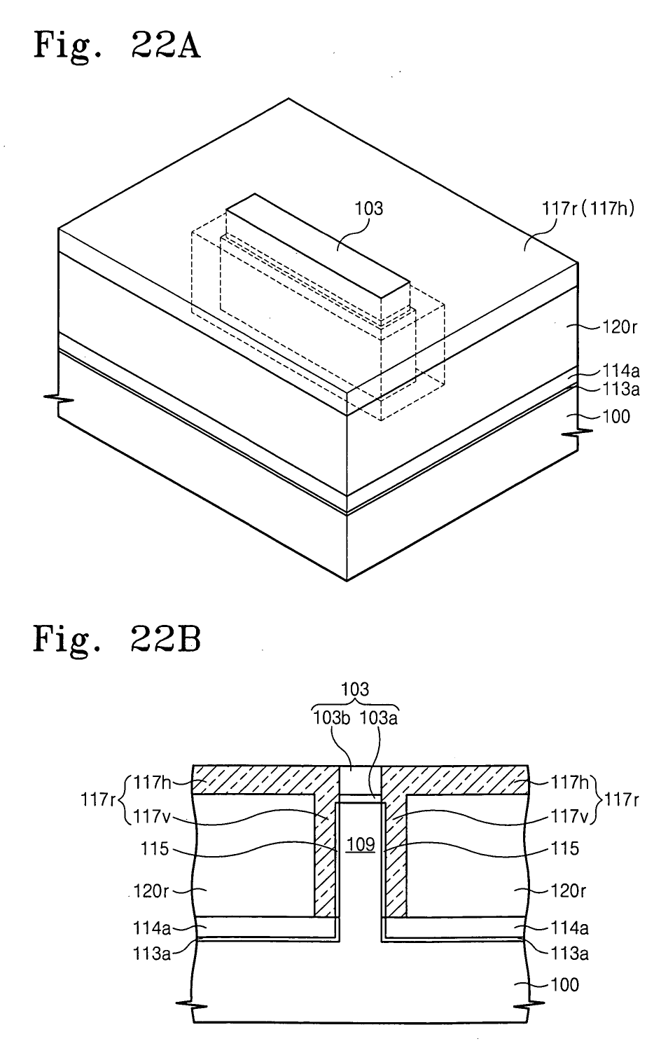

Referring to FIGS. 22A and 22B, the silicon layer 117 is planarized until the capping layer 103 is exposed, thereby reducing the height of the silicon layer 117. As such, a top surface of the recessed silicon layer 117r may be similar in height to the capping layer 103. The recessed silicon layer 117r includes a vertical portion 117v and a horizontal portion 117h. The vertical portion 117v fills the trench region 118 and is formed on sidewalls of the semiconductor fin 105 and the capping layer 103. The horizontal portion 117h extends laterally on the recessed upper insulation layer 120r and may be practically orthogonal to the vertical portion 117r. Thus, the horizontal portion 117h may be formed on an entire top surface of the recessed upper insulation layer 120r, and the top surface of the horizontal portion 117h may be about the same height as that of the capping layer 103. Alternatively, in some embodiments, the top surface of the horizontal portion 117h may be over etched during the planarization process and/or etched back after planarization so as to be lower than the top surface of the capping layer 103.

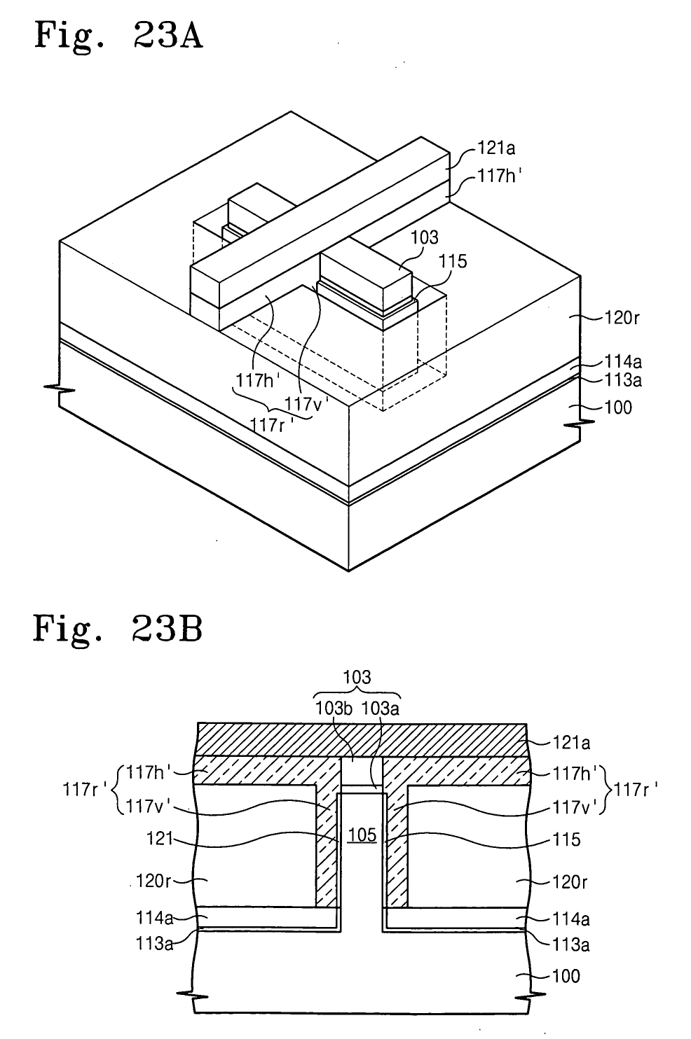

Next, referring to FIGS. 23A and 23B, a low resistance metal layer for use as a word line is formed on the capping layer 103 and the recessed silicon layer 117r, and then a gate etch mask (not shown) is formed on the metal layer. The portions of the low-resistance metal layer that are exposed by the gate etch mask are then etched to form a metal pattern 121a crossing over the semiconductor fin 105. The recessed silicon layer 117r at both sides of the metal pattern 121a is then selectively etched to form a silicon pattern 117r′. As a result, the silicon pattern 117r′ may remain under the metal pattern 121a, on the opposing sidewalls of the semiconductor fin 105 and the capping layer 103, and on the top surface of the recessed upper insulation layer 120r. More specifically, the silicon pattern 117r′ includes the vertical portion 117v′ under the low-resistance metal pattern 121a on sidewalls of the semiconductor fin 105 and the capping layer 103, and the horizontal portion 117h′ under the metal pattern 121a on the recessed upper insulation layer 120r (i.e., between the metal pattern 121a and the recessed upper insulation layer 120r).

A silicidation process is then performed to convert the silicon pattern 117r′ into a silicide. As described above, a high-melting point metal layer (not shown) is formed on an entire surface of the substrate 120 including in the trench region 118 adjacent opposing sidewalls of the silicon pattern 117r′, and then a thermal process is performed to convert the silicon pattern 117r′ into a silicide layer to form a silicide gate electrode by siliciding the opposing sidewalls of the silicon pattern 117r′ towards a central portion thereof.

Next, a gate ion implantation process is applied to the silicide gate electrode. The gate ion implantation process may employ tilted ion implantation. The tilted ion implantation process may use the recessed upper insulation layer 120r and the capping layer 103 as an ion implantation mask to implant impurity ions into the silicide gate electrode (at vertical portion 117v′) on sidewalls of the semiconductor fin 105.

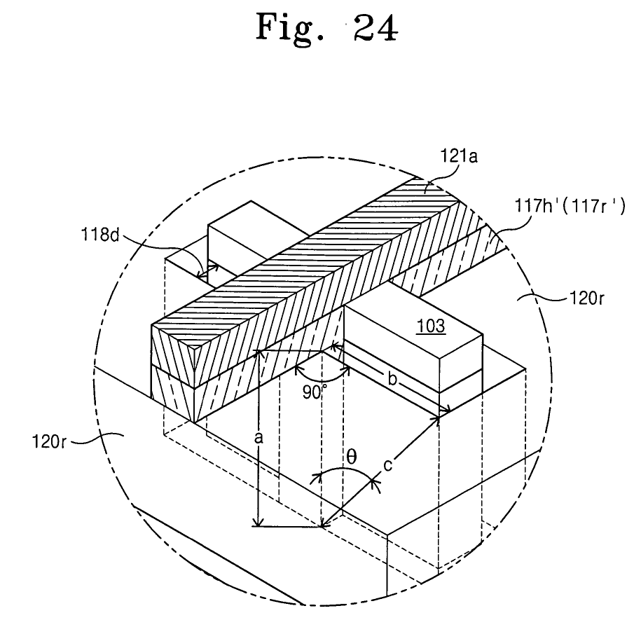

FIG. 24 illustrates an enlarged portion of FIG. 23A. Referring now to FIG. 24, the tilted ion implantation angle is ‘θ’. The tilted ion implantation angle ‘θ’ may be calculated as follows. The distance ‘b’ from a sidewall of the silicon pattern 117r′ to a sidewall of the upper insulation layer 120r is known. The height ‘a’ of the upper recessed insulation layer 120r from a bottom of the silicon pattern 117r′ (i.e., the height of the recessed upper insulation layer 120r measured from the buffer insulation layer 114a) is also known. Therefore, a distance ‘c’ from the bottom of the silicon pattern 117r′ to the top surface of the recessed upper insulation layer 120r can be calculated by the Pythagorean theorem. As a result, the tiled ion implantation angle ‘θ’ can be calculated.

In addition, the ion implantation angle ‘θ’ may be calculated using trigonometry, as cos θ=(a/c) and tan θ=(b/a). The ion implantation process for forming source/drain regions may also be performed using the tilted ion implantation technique.

Thus, according to embodiments of the present invention, the threshold voltage of a fin field effect transistor may be adjusted and/or reduced by forming a first gate electrode of a silicide layer on opposing sidewalls of a silicon fin. In addition, a second gate electrode may be formed of low-resistance material to reduce RC delay and thereby improve device operation speed.

While the present invention has been particularly shown and described with reference to embodiments thereof, it will be understood by those skilled in the art that various changes in form and details may be made therein without departing from the spirit and scope of the invention as defined by the appended claims and their equivalents.

1. A method of fabricating a fin field-effect transistor, the method comprising:
forming a fin-shaped active region having first and second source/drain regions therein and a channel region therebetween vertically protruding from a semiconductor substrate;
forming a polysilicon gate electrode on sidewalls of the channel region; and
siliciding opposing sidewalls of the polysilicon gate electrode towards a central region thereof to form a silicide gate electrode.

2. The method of claim 1, wherein siliciding opposing sidewalls of the polysilicon gate electrode comprises:
forming a refractory metal layer on the opposing sidewalls of the polysilicon gate electrode; and
annealing the refractory metal layer to silicide the polysilicon gate electrode from an interface between the refractory metal layer and the opposing sidewalls of the polysilicon gate electrode towards the central region thereof.

3. The method of claim 1, further comprising:
forming a metal gate electrode on an upper surface of the polysilicon gate electrode.

4. The method of claim 3, further comprising:
forming a metal nitride layer on the upper surface of the polysilicon gate electrode prior to forming the metal gate electrode thereon to prevent silicidation therebetween.

5. The method of claim 4, wherein the metal gate electrode comprises a word line comprising tungsten, molybdenum, and/or titanium, and wherein the metal nitride layer comprises titanium nitride and/or tungsten nitride.

6. The method of claim 1, further comprising:
forming a gate insulation layer on an upper surface and on the sidewalls of the channel region; and
forming the polysilicon gate electrode on the upper surface of the channel region to form a triple-gate FinFET device.

7. The method of claim 1, further comprising:
forming a capping insulation layer on an upper surface of the fin-shaped active region between the polysilicon gate electrode and the channel region to form a double-gate FinFET device.

8. The method of claim 1, further comprising:
forming a lower insulation layer on the substrate adjacent lower sidewalls of the fin-shaped active region; and
forming an upper insulation layer on the lower insulation layer to define a trench surrounding the fin-shaped active region,
wherein forming a polysilicon gate electrode comprises forming a vertical portion of the polysilicon gate electrode in the trench on the sidewalls of the channel region and forming a horizontal portion of the polysilicon gate electrode on an upper surface of the upper insulation layer.

9. The method of claim 8, wherein forming an upper insulation layer comprises:
forming the upper insulation layer to extend away from the substrate to a height greater than that of the fin-shaped active region.

10. The method of claim 8, further comprising:
doping the silicide gate electrode and/or the first and second source/drain regions exposed by the trench using a tilted ion implantation process.

11. A method of forming a fin field-effect transistor, the method comprising:
forming a fin-shaped active region having first and second source/drain regions therein and a channel region therebetween vertically protruding from a semiconductor substrate;
forming a lower insulation layer on the substrate adjacent lower sidewalls of the fin-shaped active region; and
forming an upper insulation layer on the lower insulation layer to define a trench surrounding the fin-shaped active region;
forming a polysilicon gate electrode comprising a vertical portion in the trench on sidewalls of the channel region and a horizontal portion on an upper surface of the upper insulation layer;
forming a metal nitride layer on an upper surface of the polysilicon gate electrode;
forming a metal gate electrode on the metal nitride layer;
forming a refractory metal layer on opposing sidewalls of the polysilicon gate electrode, the metal nitride layer, and the metal gate electrode; and
annealing the refractory metal layer to form a silicide gate electrode having an increasing degree of silicidation from an interface between the refractory metal layer and opposing sidewalls of the silicide gate electrode towards a central region thereof.

12. A FinFET device, comprising:
a semiconductor substrate;
a fin-shaped active region having first and second source/drain regions therein and a channel region therebetween vertically protruding from the semiconductor substrate; and
a silicide gate electrode on sidewalls of the channel region, the silicide gate electrode having an increasing degree of silicidation from opposing sidewalls thereof towards a central region thereof.

13. The device of claim 12, further comprising:
a metal gate electrode on an upper surface of the silicide gate electrode.

14. The device of claim 13, further comprising:
a metal nitride layer on the upper surface of the silicide gate electrode between the metal gate electrode and the silicide gate electrode.

15. The device of claim 14, wherein the metal gate electrode comprises a word line comprising tungsten, molybdenum, and/or titanium, and wherein the metal nitride layer comprises titanium nitride and/or tungsten nitride.

16. The device of claim 12, further comprising:
a gate insulation layer on an upper surface and on the sidewalls of the channel region,
wherein the silicide gate electrode extends onto the upper surface of the channel region to define a triple-gate FinFET device.

17. The device of claim 12, further comprising:
a capping insulation layer on an upper surface of the fin-shaped active region,
wherein the capping layer separates the silicide gate electrode and an upper surface of the channel region to define a double-gate FinFET device.

18. The device of claim 17, wherein the silicide gate electrode extends away from the substrate on the sidewalls of the channel region to a height approximately equal to that of the capping layer.

19. The device of claim 12, further comprising:
a lower insulation layer on the substrate adjacent lower sidewalls of the fin-shaped active region; and
an upper insulation layer on the lower insulation layer defining a trench surrounding the fin-shaped active region,
wherein the silicide gate electrode comprises a vertical portion in the trench on the sidewalls of the channel region and a horizontal portion on an upper surface of the upper insulation layer.

20. The device of claim 19, wherein the upper insulation layer extends away from the substrate beyond the fin-shaped active region.

21. The device of claim 12, wherein the silicide gate electrode is doped with n type or p type impurities, and wherein the source/drain regions include the same type impurities doped in the silicide gate electrode.

22-44. (canceled)
